(19) United States
(12) Patent Application Publication
(10) Pub. No.: US 2018/0080363 A1
(43) Pub. Date: Mar. 22, 2018

(54) THERMOELECTRIC GENERATOR, IN PARTICULAR FOR A MOTOR VEHICLE

(71) Applicant: Mahle International GmbH, Stuttgart (DE)

(72) Inventors: Matthias Ganz, Stuttgart (DE); Stefan Hirsch, Stuttgart (DE); Christopher Laemmle, Stuttgart (DE); Volker Schall, Hemmingen (DE)

(21) Appl. No.: 15/708,087

(22) Filed: Sep. 18, 2017

(30) Foreign Application Priority Data
Sep. 19, 2016 (DE) 10 2016 217 904.7

(51) Int. Cl. F01N 5/02

(52) U.S. Cl. CPC F01N 5/025; H01L 35/04

(57) ABSTRACT

A thermoelectric generator for a motor vehicle may include a plurality of first stacking disks and a plurality of second stacking disks. The plurality of first stacking disks and the plurality of second stacking disks may be alternately stacked in a stacking direction and may each be shell shaped. The alternately stacked plurality of first stacking disks and second stacking disks may form a plurality of stacking disk pairs. The plurality of stacking disk pairs may each include a first stacking disk and a second stacking disk adjacent to the first stacking disk in the stacking direction. The first stacking disk and the second stacking disk may define a gas path. At least one intermediate space may be defined between adjacent stacking disk pairs. At least one tubular body may be disposed within the at least one intermediate space and may define at least one coolant path. The gas path may be traversed by a gas having a first temperature higher than a second temperature of a coolant flow through the at least one coolant path. At least one thermoelectric module having at least one thermoelectrically active element may be interposed within the at least one intermediate space between the gas path and the at least one coolant path. The thermoelectric module may include a hot side in thermal contact with the gas path, and a cold side in thermal contact with the coolant path.

### CROSS-REFERENCE TO RELATED APPLICATIONS

This applications claims priority to German Patent Application No.: DE 10 2016 217 904.7 filed on Sep. 19, 2016, the contents of which are incorporated herein by reference.

### TECHNICAL FIELD

The invention concerns a thermoelectric generator, in particular for a motor vehicle.

### BACKGROUND

The term “thermoelectricity” is understood to mean the mutual influence of temperature and electricity and their interaction. Thermoelectric modules with, in each case, a plurality of thermoelectrically active elements, make use of this effect in order to generate electrical energy from waste heat as thermoelectric generators. The said thermoelectric elements consist for this purpose of thermoelectric semiconductor materials, which convert a temperature difference into a potential difference, that is to say, into an electrical voltage. In this manner, a heat flow can be converted into an electric current. The thermoelectric modules are based on the Seebeck effect. Within a thermoelectric module, p-doped and n-doped thermoelectric elements are interconnected. A plurality of such thermoelectric modules are usually connected to form a thermoelectric generator, which can generate an electrical current from a temperature difference in conjunction with a corresponding heat flow. Here it is of great importance to achieve the highest possible efficiency in order to convert heat to electrical energy as effectively as possible.

### SUMMARY

It is therefore an object of the present invention to demonstrate new ways of developing thermoelectric generators. In particular, a thermoelectric generator is to be created, which has a particularly high efficiency.

This object is achieved by the subject matter of the independent patent claims. Preferred embodiments are the subject matter of the dependent claims.

A thermoelectric generator in accordance with the invention, in particular for a motor vehicle, comprises a plurality of first and second stacking disks alternately stacked one upon another along a stacking direction. Both the first and the second stacking disks are designed in the form of a shell. In each case a first stacking disk and a second stacking disk, adjacent to the latter in the stacking direction, form a stacking disk pair. Each stacking disk pair bounds a gas path. In at least one intermediate space between two adjacent stacking disk pairs, a coolant path is formed, which is bounded by a tubular body. In accordance with the invention, the gas path is traversed by a gas with a temperature that has a higher value than a temperature of the coolant flowing through the at least one coolant path.

In at least one intermediate space between a gas path and a coolant path, a thermoelectric module with at least one thermoelectrically active element is arranged. The said thermoelectric module has a hot side, which is in thermal contact with the gas path adjacent to the stacking direction, and a cold side, which is in thermal contact with the coolant path adjacent in the stacking direction. This ensures a highly effective thermal contact of the thermoelectrically active elements with the gas flowing through the gas paths, as well as with the coolant flowing through the coolant paths. In this manner, a high efficiency of the thermoelectric generator can be ensured.

In a preferred embodiment, two stacking disk pairs adjacent in the stacking direction communicate with each other by means of at least one gas path connecting line, namely, which is in fact separated from the respective intermediate space between the two stacking disk pairs in terms of fluid flow. A variant in which two gas path connecting lines are arranged at a distance from one another is to be seen as particularly preferred. This enables a simple distribution of the gas to the existing gas paths as well as a simple collection of the gas after it has flowed through the individual gas paths. In particular, a single common inlet and a single common outlet are sufficient to introduce the gas into the gas paths and to remove the gas from the latter once again, since the distribution to the individual gas paths can take place via the said gas path connecting lines. In this embodiment, a first and/or second stacking disk of a particular pair of stacking disks has, for the design of the at least one gas path connecting line, a thermal expansion compensation dome protruding from the respective stacking disk and enclosing a passage opening. Such a thermal expansion compensation dome also possesses the second and first stacking disks of the pair of stacking disks adjacent in the stacking direction. In this manner, the two thermal expansion compensation domes adjacent in the stacking direction bound the respective gas path connecting line between the stacking disks adjacent in the stacking direction.

Expediently, at least one thermal expansion compensation dome is designed such that it compensates for thermally induced expansions of the material of the stacking disk pairs, in particular in the stacking direction. If the stacking disks of the stacking disk pairs extend in the stacking direction because of the high temperature of the hot gas flowing through the gas path, this thermal expansion in the stacking direction can be compensated for by the thermal expansion compensation domes. In this manner, any damage to the structure of individual components of the thermoelectric generator due to thermal expansion of the stacking disk pairs is prevented. A gap is also prevented from forming between the thermoelectric modules and the stacking disks adjacent to them, which gap would reduce the contact of the gas path with the hot side.

In an advantageous development, at least one thermal expansion compensation dome has a collar-like peripheral wall protruding from the stacking disk in the stacking direction, which encloses the said passage opening. Particularly preferably, the peripheral wall tapers away from the stacking disk along the stacking direction. This permits a simple, yet mechanically robust, configuration of the respective gas path connecting lines.

In order to achieve a durable, fluid-tight connection, it is advisable to connect adjacent thermal expansion compensation domes in the stacking direction with one another in a material bond. A brazed joint, which can be produced in a simple manner for all existing thermal expansion compensation domes in a brazing furnace, proves to be particularly advantageous.

In another preferred embodiment, the thermal expansion compensation domes adjoining the gas path connecting line in the stacking direction are connected directly or indirectly, specifically by means of a connecting tubular body. The first variant is structurally particularly simple and thus particularly cost-effective to implement. The latter variant is structurally somewhat more complex to implement, but in particular permits a flexible determination of the distance between two adjacent pairs of stacking disks. Particularly preferably, such a connecting tubular body is designed as a hollow cylinder, which can be connected to the two associated thermal expansion compensation domes in a material bond, preferably by means of a brazed joint.

Particularly preferably, a ribbed structure is provided between the first and second stacking disks of at least one pair of stacking disks, which is supported on the first and second stacking disks. In this manner, the pairs of stacking disks can be mechanically stiffened. At the same time, the active cross-sectional area of the respective stacking disks is improved with the gas flowing through the pairs of stacking disks.

Particularly preferably, at least two second coolant paths, in particular at least two tubular bodies, are provided between two thermoelectric modules adjacent in the stacking direction, which are arranged adjacent to one another, preferably at a distance from one another, along the first longitudinal direction. These measures result in an improved thermal contact between the coolant flowing through the coolant paths and the thermoelectrically active elements, which increases the efficiency of the thermoelectric generator.

The first and second stacking disks are also particularly preferably designed as half-shells, which face each other so as to bound a gas path. This measure simplifies the production of the said stacking disks, which results in cost advantages, in particular if the first and second stacking disks are produced as identical parts.

Particularly preferably, at least one thermoelectric module has a plurality of thermoelectrically active elements, which are arranged in a grid-like manner at right angles to the stacking direction, and are connected to one another by means of electrical conductor elements, preferably made of copper. This ensures a highly effective thermal contact of the thermoelectrically active elements with the gas flowing through the gas paths, as well as with the coolant flowing through the coolant paths.

Particularly expediently, electrically insulating insulation can be arranged on an outer side of the first stacking disk of a pair of stacking disks facing away from the second stacking disk, and on an outer side of the second stacking disk of a pair of stacking disks facing away from the first stacking disk. In this manner, the electrical wiring required for the proper functioning of the thermoelectric module can be achieved between the individual thermoelectrically active elements. In particular, undesirable electrical short-circuits between the thermoelectrically active elements via the typically electrically conductive material of the stacking disks or the tubular bodies are avoided.

Particularly preferably, the electrical insulation is designed as an insulation layer or as an insulation film, in particular of a plastic material, which together with the electrical conductor elements is materially bonded to the stacking disk adjacent in the stacking direction. This allows a durable attachment of the electrical insulation or of the electrical conductor elements to the stacking plate, even if these are heated to temperatures of up to 600° C. or more during the passage of the hot gas.

Particularly preferably, at least a first stacking disk, as well as—alternatively or additionally—at least one second stacking disk, has a peripheral edge protruding in the stacking direction. This measure facilitates the attachment of the two stacking disks, preferably by means of material bonding, to form a gas path. The said edges also serve to compensate for any thermal expansion of the stacking disks that may arise.

In an advantageous further development, at least one tubular body forming a coolant path is designed as a flat tube whose tube height, measured along the stacking direction, is at most one-fifth, preferably at most one-tenth, of a tube width measured transversely to the tube height. In this manner, the space requirement of the thermoelectric generator in the stacking direction can be kept small.

In a further preferred embodiment, the rib-like structure is arranged laterally, that is to say, in a plane perpendicular to the stacking direction, essentially in the same region as the thermoelectrically active elements of the thermoelectric modules. In this manner, a particularly high stiffening of the thermoelectric generator in the region of the thermoelectrically active elements, which are particularly sensitive to mechanical pressure, is ensured.

In an advantageous further development of the invention at least one gas path extends along a first longitudinal direction, and at least one coolant path along a second longitudinal direction. In this variant, the second longitudinal direction extends transversely to the first longitudinal direction. Both longitudinal directions in turn run transversely to the stacking direction. This allows the gas to be introduced or discharged—typically by means of a gas inlet or gas outlet in a direction transverse to the introduction or discharge of the coolant—typically by means of a (second) coolant inlet or coolant outlet. The connections required for this purpose can therefore advantageously be positioned offset by 90° relative to one another.

Further important features and advantages of the invention ensue from the subsidiary claims, from the drawings and from the associated description of the figures with the aid of the drawings.

It goes without saying that the features mentioned above, and those that are still to be explained below, can be used not only in the respective combination specified, but also in other combinations, or in a single setting, without departing from the scope of the present invention.

Preferred examples of embodiments of the invention are illustrated in the drawings and are explained in greater detail in the following description, wherein like reference symbols refer to identical, or similar, or functionally identical, components.

### BRIEF DESCRIPTION OF THE DRAWINGS

In schematic representations:

FIG. 1 shows an example of a thermoelectric generator in accordance with the invention in an assembled state;

FIG. 2 shows the thermoelectric generator of FIG. 1 in a partially assembled state;

FIG. 3 shows in a perspective illustration into a first stacking disk of an arbitrary stacking disk pair, and a second stacking disk of the stacking disk pair adjacent in the stacking direction S;

FIG. 4 shows the illustration of FIG. 3 in a side view;

FIG. 5 shows a variant of the example of FIG. 3;

FIG. 6 shows the illustration of FIG. 5 in a longitudinal section along the stacking direction of the thermoelectric generator;

FIGS. 7, 8 show a first stacking disk of the thermoelectric generator during assembly in a separate illustration.

### DETAILED DESCRIPTION OF THE DRAWINGS

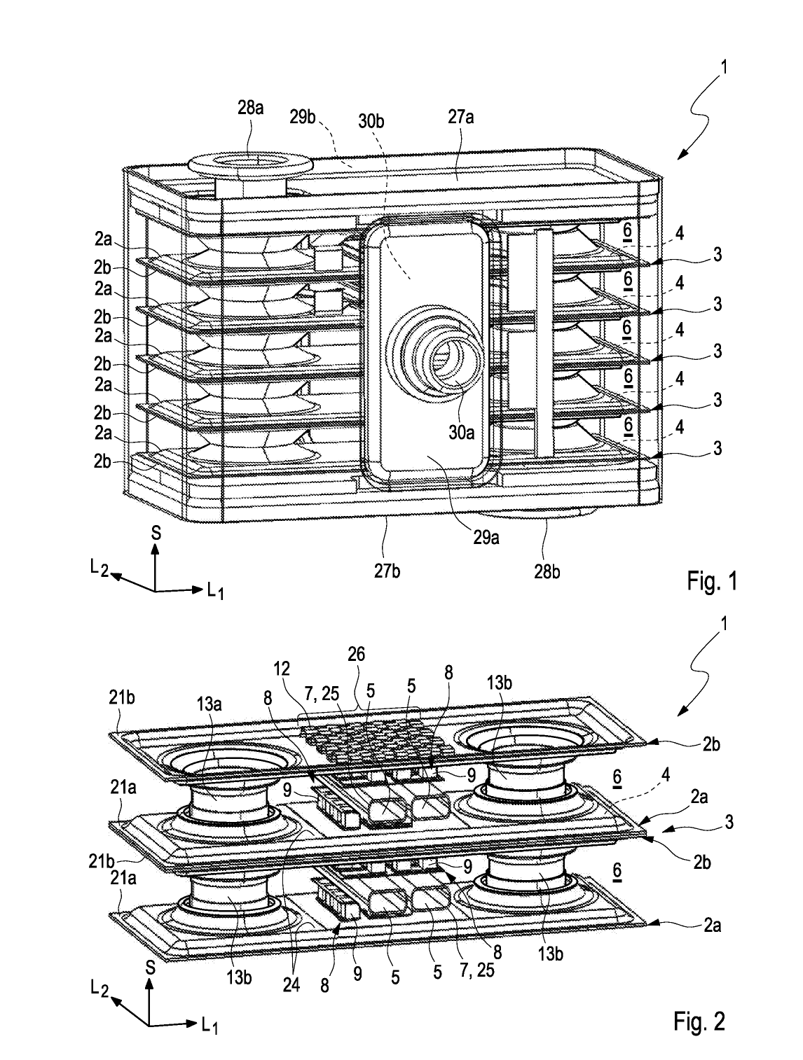

FIGS. 1 and 2 each show a perspective illustration of an example of a thermoelectric generator 1 in accordance with the invention for a motor vehicle. FIG. 1 shows the thermoelectric generator 1 in a completely assembled state; FIG. 2 in a partially assembled state.

In accordance with FIGS. 1 and 2 the thermoelectric generator 1 comprises a plurality of first and second stacking disks 2a, 2b, alternately stacked one on top of the other in a stacking direction S; each being designed in the form of a shell. In each case, a stacking disk pair 3 of a first and a second stacking disk 2a, 2b bound a gas path 4, through which a gas can flow. The first and second stacking disks 2a, 2b of a respective stacking disk pair 3 are designed as half-shells, which face each other so as to bound the gas path 4.

For purposes of compensation for thermal expansion the first and second stacking disks 2a, 2b each have a peripheral edge 21a, 12b protruding in the stacking direction S. (cf. FIG. 2). The first and second stacking disks 2a, 2b of a respective stacking disk pair 3 can in this manner be materially bonded with one another in a particularly simple manner, in particular by means of brazing, so as to form a respective gas path 4. A ribbed structure 12 can be arranged between the first and second stacking disks 2a, 2b of a respective stacking disk pair 3, which ribbed structure is supported on the first and second stacking disks 2a, 2b. The ribbed structure 12 serves to provide mechanical stiffening of the stacking disk pair 3. At the same time the ribs 12 can act as turbulence generation elements for the gas flowing through the gas path 4. The above-mentioned ribbed structure 12 is arranged laterally, that is to say, in a plane at right angles to the stacking direction S, essentially in the same region 26 as the thermoelectrically active elements 9 of the thermoelectric modules 8.

In the intermediate spaces 6 between two adjacent gas paths 4 in the stacking direction S coolant paths 5 are provided, through which—separated in terms of fluid flow from the gas paths 4—a coolant can flow. The coolant paths 5 are bounded by respective tubular bodies 7. Thermoelectric modules 8 with thermoelectrically active elements 9 are also arranged in the intermediate spaces 6 between the gas paths 4 and the coolant paths 5. In the exemplary scenario, two thermoelectric modules 8 are provided in each intermediate space 6, between which at least one coolant path 5 is arranged in the form of a sandwich in the stacking direction S.

As can also be seen in FIG. 2, the gas paths 4 are of longitudinal design—their channel length is at least three times, preferably at least five times their channel width, and extend along a first longitudinal direction L1. FIG. 2 also shows that between two thermoelectric modules 8 adjacent in the stacking direction S are arranged two coolant paths 5 or tubular bodies 7, which are arranged adjacent to one another and at a distance from one another along the first longitudinal direction L1, In variants the number of coolant paths 5 or tubular bodies 7 can vary. In particular a possible variant is one with only a single coolant path 5 or tubular body 7 per intermediate space 6.

The coolant paths 5 as well as the gas paths 4 are also of longitudinal design—their channel length thus being at least three times, preferably at least five times their channel width—and they extend along a second longitudinal direction L2, which runs transversely to the first longitudinal direction L1. The tubular bodies 7 forming the coolant paths 5 can preferably be designed as flat tubes 25, whose tube height measured along the stacking direction S is at most one-fifth, preferably at most one-tenth, of a tube width measured transversely to the tube height.

The thermoelectric modules 8 in each case possess a hot side and a cold side. The hot side of a respective thermoelectric module 8 is in thermal contact with the gas path 4 adjacent in the stacking direction S. The cold side of the same thermoelectric module 8 is in thermal contact with the coolant path 5 adjacent in the stacking direction S. A gas flows through the gas paths 4 at a temperature that is higher than a temperature of the coolant flowing through the coolant paths 5. The resulting temperature difference between the hot side and the cold side causes the thermoelectric modules 8 to generate an electrical voltage.

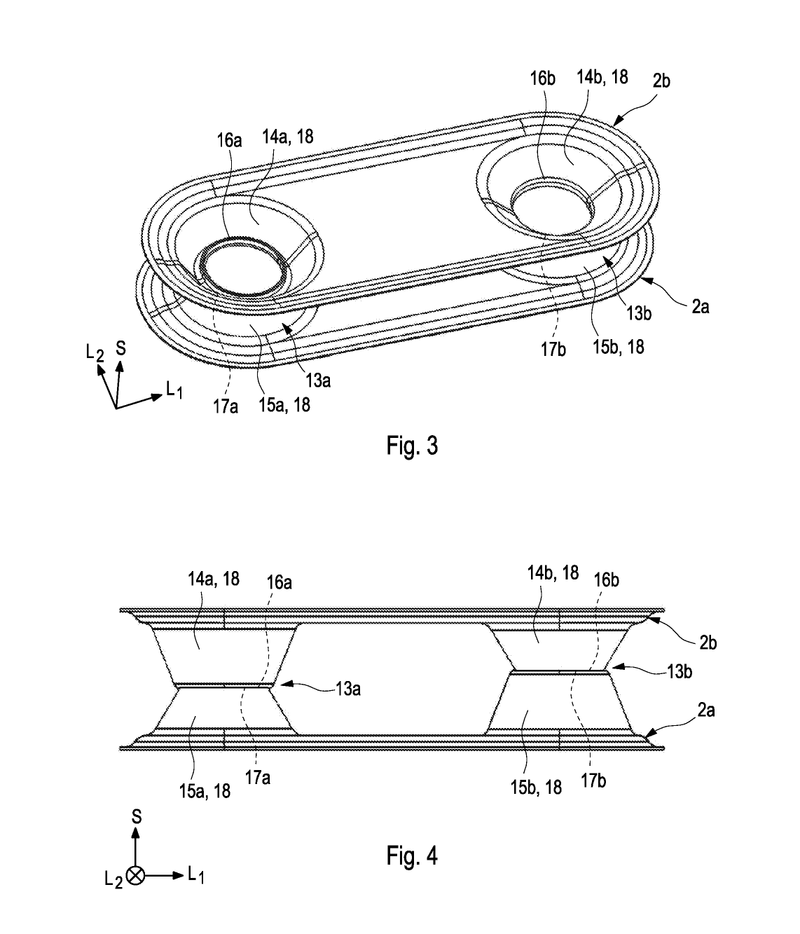

In what follows, the focus is on what is being represented in FIGS. 3 and 4: FIG. 3 shows a perspective illustration of a first stacking disk 2a of an arbitrary stacking disk pair 3 and a second stacking disk 2b of the stacking disk pair 3 adjacent in the stacking direction S. FIG. 4 shows the stacking disks 2a, 2b of FIG. 3 in a side view.

In accordance with FIGS. 3 and 4, the two stacking disk pairs 3 adjacent in the stacking direction S are connected to one another in terms of fluid flow by means of two gas path connecting lines 13a, 13b arranged at a distance from one another. For this purpose, the first stacking disk 2a shown in FIGS. 3 and 4 has two thermal expansion compensation domes 14a, 14b protruding from the first stacking disk 2a towards the second stacking disk 2b adjacent in the stacking direction S. In an analogous manner, the second stacking disk 2b shown in FIGS. 3 and 4 has two thermal expansion compensation domes 15a, 15b protruding from the second stacking disk 2b in the stacking direction S towards the adjacent first stacking disk 2a.

The thermal expansion compensation domes 14a, 14b, 15a, 15b are designed such that thermal expansion of the material of the stacking disk pairs 3, in particular in the stacking direction S, is compensated by them. If the stacking disks 2a, 2b of the stacking disk pairs 3 extend in the stacking direction S by virtue of the high temperature of the hot gas flowing through the gas paths 4, this thermal expansion in the stacking direction S can be compensated for by the thermal expansion compensation domes 14a, 14b, 15a, 15b. In this manner, any damage to the structure of individual components by virtue of the thermal expansion of the stacking disk pairs 3 in the stacking direction S is prevented.

The thermal expansion compensation domes 14a, 15a, and 14b, 15b, adjacent in the stacking direction S in each case bound a gas path connecting line 13a, 13b of adjacent stacking disk pairs 3 in the stacking direction S. Each thermal expansion compensation dome 14a, 14b, 15a, 15b comprises a collar-like peripheral wall 18, protruding from the respective stacking disk 2a, 2b in the stacking direction S, and enclosing the respective passage opening 16a, 16b, 17a, 17b. The peripheral walls 18 preferably taper along the stacking direction S away from the respective stacking disk 2a, 2b. For the formation of a respective gas path connection line 13a, adjacent thermal expansion compensation domes 14a, 14b, 15a, 15 in the stacking direction S are materially bonded with one another, preferably by means of a brazed joint.

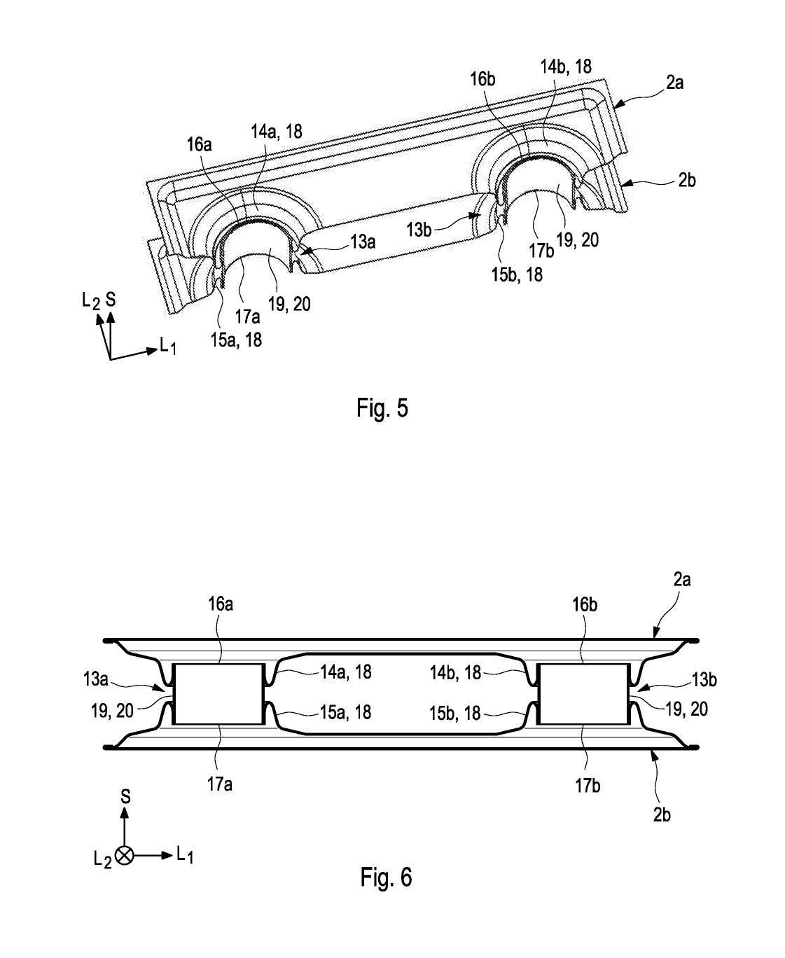

FIGS. 5 and 6 show a variant of the example of FIGS. 3 and 4. FIG. 6 shows a longitudinal section of the stacking disk 2a in FIG. 5 along the stacking direction S. In the variant shown in FIGS. 5 and 6, the thermal expansion compensation domes 14a, 15a and 14b, 15b adjacent in the stacking direction S are used to form a respective gas path connecting line 13a, 13b by means of a connecting tubular body 19, which can preferably be designed as a hollow cylinder. The thermal expansion compensating domes 14a, 15a and 14b, 15b can each be materially bonded to the connecting tube body 19, preferably by means of a brazed joint.

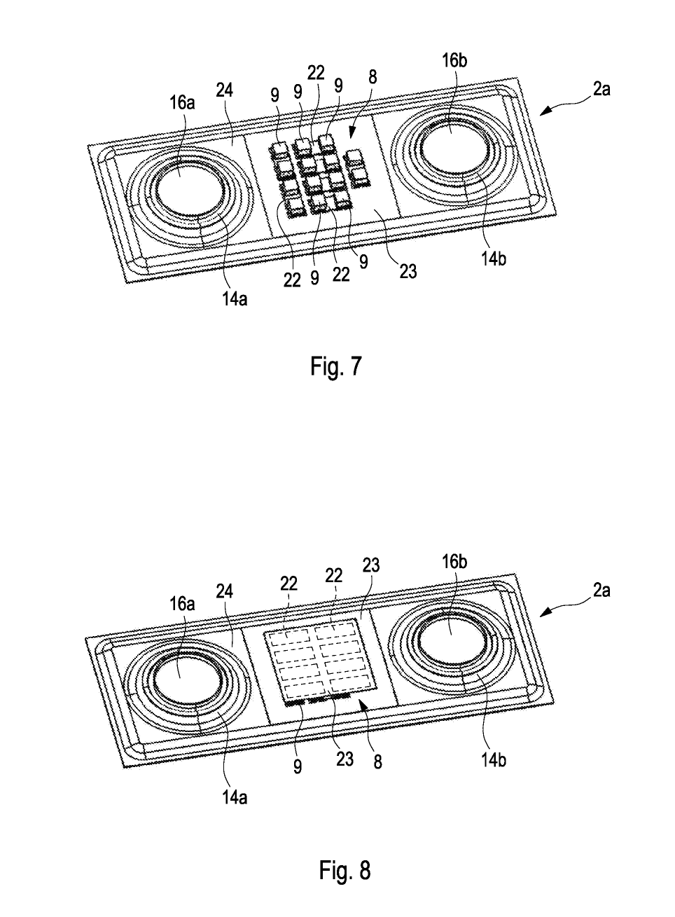

FIG. 7 shows a first stacking disk 2a in a separate illustration. It can be seen that the thermoelectric module 8 shown in FIG. 7 in each case has a plurality of thermoelectrically active elements 9, which are arranged in a grid-like manner relative to one another in a cross-section at right angles to the stacking direction S. The thermoelectrically active elements 9 are connected to one another by means of electrical conductor elements 22 so as to form the thermoelectric generator 1. The thermoelectrically active elements 9 are arranged on an outer side 24 of the first stacking disk 2a which faces away from the second stacking disk 2b of the same stacking disk pair 3 (not shown in FIG. 7). Electrical insulation 23 is arranged between the outer side 24 of the first stacking disk 2a and the thermoelectrically active elements 9 with the electrical conductor elements 22. The electrical insulation 23 can be designed as an insulation film or as an insulation layer made of an electrically insulating material, preferably a plastic. The electrical insulation 23, together with the electrical conductor elements 22, can be materially bonded with the stacking disk 2a or 2b adjacent in the stacking direction S. This applies mutatis mutandis to the electrical conductor elements 22.

In an analogous manner to the first stacking disk 2a, thermoelectrically active elements 9 with electrical conductor elements 22 and electrical insulation 23 are also arranged on the second stacking plate 2b (not shown in FIG. 7, cf. on this point, however, FIG. 2). As part of the thermoelectric modules 8, electrical conductor elements 22 and electrical insulation 23 are also provided between the thermoelectric elements 9 and the tubular bodies 7 forming the coolant paths 5. This is depicted by the illustration of FIG. 8 (in conjunction with FIG. 2).

Referring once again to FIG. 1, it can be seen that a connection 28a, 28b is provided on each of the two sides 27a, 27b of the thermoelectric generator 1, which are opposite in the stacking direction S, the said connection being designed for introducing and distributing the gas into/onto the gas paths 4, or for collecting and discharging the gas after it has flowed through the gas paths 4. For this purpose, the two connections 28a, 28b communicate in terms of fluid flow with the gas paths 4. In an analogous manner, a connection 30a, 30b can also be provided on two sides 29a, 29b of the thermoelectric generator 1, which are opposite in the second longitudinal direction of extension L2 (only one such connection is visible in FIG. 1; the connection opposite thereto is concealed in FIG. 1); this is designed for introducing and distributing the coolant to the coolant paths 5, or for collecting and discharging the coolant after it has flowed through the coolant paths 5. For this purpose, the two connections 30a, 30b communicate in terms of fluid flow with the coolant paths 5.

1. A thermoelectric generator for a motor vehicle comprising:
a plurality of first stacking disks and a plurality of second stacking disks, wherein the plurality of first stacking disks and the plurality of second stacking disks are alternately stacked in a stacking direction, and wherein each of the plurality of first stacking disks and each of the plurality of second stacking disks are shell shaped;
wherein the alternately stacked plurality of first stacking disks and second stacking disks form a plurality of stacking disk pairs, wherein the plurality of stacking disk pairs each include a first stacking disk and a second stacking disk adjacent to the first stacking disk in the stacking direction, wherein the first stacking disk and the second stacking disk define a gas path;
wherein at least one intermediate space is defined between each adjacent stacking disk pair, and wherein at least one tubular body is disposed within the at least one intermediate space and defines at least one coolant path;
wherein the gas path is traversed by a gas having a first temperature, wherein the first temperature is higher than a second temperature of a coolant flow through the at least one coolant path; and
at least one thermoelectric module having at least one thermoelectrically active element interposed within the at least one intermediate space between the gas path and the at least one coolant path, wherein the thermoelectric module includes a hot side in thermal contact with the gas path, and a cold side in thermal contact with the coolant path.

2. The thermoelectric generator in accordance with claim 1, wherein at least a first stacking pair of the plurality of stacking pairs and a second stacking pair of the plurality of stacking pairs adjacent to the first stacking pair in the stacking direction are in fluid communication via at least one gas path connecting line; wherein one of the first stacking disk and the second stacking disk of the at least first stacking disk pair includes a first thermal expansion compensation dome and one of the second stacking disk and the first stacking disk of the second stacking disk pair adjacent in the stacking direction to the first stacking disk pair includes a second thermal expansion compensation dome, and wherein the first thermal expansion compensation dome protrudes toward the at least one second stacking disk pair, adjacent to the at least one first stacking disk pair, and wherein the first thermal expansion compensation dome and the second thermal expansion compensation dome surround at least one passage opening, and define the gas path connecting line between the first stacking disk and the second stacking disk adjacent to the first stacking disk in the stacking direction.

3. The thermoelectric generator in accordance with claim 2, wherein at least one of the first thermal expansion compensation dome and the second thermal expansion compensation dome is constructed and arranged to compensate for thermally induced expansion of the material of the plurality of stacking disk pairs.

4. The thermoelectric generator in accordance with claim 2, wherein at least one of the first thermal expansion compensation dome and the second thermal expansion compensation dome includes a collar-like peripheral wall, and wherein the collar-like peripheral wall protrudes from the stacking disk in or against the stacking direction, and wherein the collar-like peripheral wall encloses at least one of the respective passage openings.

5. The thermoelectric generator in accordance with claim 2, wherein the first thermal expansion compensation dome and the second thermal expansion compensation dome adjacent to the first thermal expansion compensation dome in the stacking direction are connected via a material bond in order to form the at least one gas path connecting line.

6. The thermoelectric generator in accordance with claim 1, further comprising a ribbed structure arranged between the first stacking disk and the second stacking disk of at least one stacking disk pair, and wherein the ribbed structure is supported on the first stacking disk and the second stacking disk.

7. The thermoelectric generator in accordance with claim 1, wherein the at least one gas path extends along a first longitudinal direction and the at least one coolant path extends along a second longitudinal direction transverse to the first longitudinal direction.

8. The thermoelectric generator in accordance with claim 1, wherein the at least one thermoelectrically active element comprises a plurality of thermoelectrically active elements connected via a plurality of electrical conductor elements.

9. The thermoelectric generator in accordance with claim 1, wherein an electrical insulation is at least one of arranged on an outer side of the first stacking disk of at least one stacking disk pair facing away from the second stacking disk, and is arranged on an outer side of the second stacking disk of at least one stacking disk pair facing away from the first stacking disk.

10. The thermoelectric generator in accordance with claim 9, wherein the electrical insulation is an insulation layer, and wherein the electrical insulation and a plurality of electrical conductor elements are materially bonded to the first stacking disk and the second stacking disk adjacent to the first stacking disk in the stacking direction.

11. The thermoelectric generator in accordance with claim 1, wherein at least one of the first stacking disk and the second stacking disk include a peripheral edge, and wherein the peripheral edge protrudes in the stacking direction.

12. The thermoelectric generator in accordance with claim 1, wherein the at least one tubular body is a flat tube having a tube height along the stacking direction at most one-fifth of a tube width transverse to the tube height.

13. The thermoelectric generator in accordance with claim 6, wherein the ribbed structure is arranged laterally in a plane at right angles to the stacking direction in an essentially same region as the plurality of thermoelectrically active elements of the at least one thermoelectric module.

14. The thermoelectric generator in accordance with claim 1, wherein the at least one thermoelectric module comprises a first thermoelectric module and a second thermoelectric module, and wherein the first thermoelectric module and the second thermoelectric module are disposed in the at least one intermediate space, and wherein the at least one coolant path is arranged in between the first thermoelectric module and the second thermoelectric module.

15. The thermoelectric generator in accordance with claim 1, wherein an electrical insulation is arranged on an outer side of the first stacking disk of at least one stacking disk pair facing away from the second stacking disk.

16. The thermoelectric generator in accordance with claim 1, wherein an electrical insulation is arranged on an outer side of the second stacking disk of at least one stacking disk pair facing away from the first stacking disk.

17. The thermoelectric generator in accordance with claim 2, wherein the at least one gas path connecting line is a first gas path connecting line and a second gas path connecting line, and wherein the first gas path connecting line is spaced a distance from the second gas path connecting line.

18. The thermoelectric generator in accordance with claim 4, wherein the collar-like peripheral wall tapers along the stacking direction away from the respective first stacking disk or the second stacking disk.

19. The thermoelectric generator in accordance with claim 8, wherein the plurality of electrical conductor elements are arranged in a grid-like manner relative to one another at right angles to the stacking direction.

20. A thermoelectric generator for a motor vehicle comprising:
a plurality of first stacking disks and a plurality of second stacking disks, wherein the plurality of first stacking disks and the plurality of second stacking disks are alternately stacked in a stacking direction, and wherein each of the plurality of first stacking disks and each of the plurality of second stacking disks are shell shaped;
wherein the alternately stacked plurality of first stacking disks and second stacking disks comprise a plurality of stacking disk pairs, wherein the plurality of stacking disk pairs each include a first stacking disk and a second stacking disk adjacent to the first stacking disk in the stacking direction, wherein the first stacking disk and the second stacking disk define a gas path;
a ribbed structure arranged between the first stacking disk and the second stacking disk of at least one stacking disk pair, and wherein the ribbed structure is supported on the first stacking disk and the second stacking disk;
wherein at least one intermediate space is defined between adjacent stacking disk pairs, and wherein at least one tubular body defines at least one coolant path;
wherein the first stacking disk includes a first thermal expansion compensation dome and the second stacking disk includes a second thermal expansion compensation dome, and wherein the first thermal expansion compensation dome and the second thermal expansion compensation dome enclose a passage opening, and wherein the first thermal expansion compensation dome of one of the plurality of stacking disk pairs and the second thermal compensation dome of an another of the plurality of stacking disk pairs adjacent to the one of the plurality of stacking disk pairs define a gas path connecting line;
wherein the gas path is traversed by a gas having a first temperature, wherein the first temperature is higher than a second temperature of a coolant flow through the at least one coolant path; and
at least one thermoelectric module having at least one thermoelectrically active element interposed within the at least one intermediate space between the gas path and the at least one coolant path, wherein the thermoelectric module includes a hot side in thermal contact with the gas path, and a cold side in thermal contact with the coolant path.
